(19) United States
(12) Patent Application Publication
(10) Pub. No.: US 2025/0277815 A1
(43) Pub. Date: Sep. 4, 2025

(54) DEVICE FOR MEASURING AND TRANSMITTING DC VOLTAGE SIGNALS AT GENERATOR TERMINALS

(71) Applicants: DATANG NORTH CHINA ELECTRIC POWER TEST AND RESEARCH INSTITUTE, Beijing (CN); CHINA DATANG CORPORATION SCIENCE AND TECHNOLOGY GENERAL RESEARCH INSTITUTE, Beijing (CN)

(72) Inventors: Zhigang REN, Beijing (CN); Jinsong WANG, Beijing (CN); Haichao YANG, Beijing (CN); Xingbin ZHANG, Beijing (CN); Nan LV, Beijing (CN); Yuxin YANG, Beijing (CN); Peng LI, Beijing (CN); Chen JIN, Beijing (CN); Yuheng MENG, Beijing (CN); Boyi LI, Beijing (CN); Yunyi GAO, Beijing (CN)

(73) Assignees: DATANG NORTH CHINA ELECTRIC POWER TEST AND RESEARCH INSTITUTE, Beijing (CN); CHINA DATANG CORPORATION SCIENCE AND TECHNOLOGY GENERAL RESEARCH INSTITUTE, Beijing (CN)

(21) Appl. No.: 19/210,830

(22) Filed: May 16, 2025

Related U.S. Application Data
(63) Continuation of application No. PCT/CN2024/124365, filed on Oct. 12, 2024.

(30) Foreign Application Priority Data
Nov. 13, 2023 (CN) 202311501930.0

(51) Int. Cl. G01R 1/20; G01R 1/067; G01R 13/02; G01R 19/00

(52) U.S. Cl. CPC G01R 1/203; G01R 1/06755; G01R 13/02; G01R 19/0084

(57) ABSTRACT

A device for measuring and transmitting DC voltage signals at generator terminals, including an insulated test rod, a roller-type measuring head, and a voltage signal display. The insulated test rod is internally provided with a standard resistor and a grounding interface. The roller-type measuring head is positioned at an outer end of the insulated test rod and is connected to the standard resistor and the grounding interface via a conductor. The voltage signal display is arranged outside the insulated test rod and is wirelessly connected to the roller-type measuring head. The present application enhances operational efficiency, reduces safety risks for personnel and equipment, benefits environmental sustainability, and improves economic outcomes.

### CROSS-REFERENCE TO RELATED APPLICATIONS

The present application claims the priority to the Chinese Patent Application No. 2023115019300, titled “DEVICE FOR MEASURING AND TRANSMITTING DC VOLTAGE SIGNALS AT GENERATOR TERMINALS”, filed on Nov. 13, 2023 with the China National Intellectual Property Administration, which is incorporated herein by reference in its entirety.

### TECHNICAL FIELD

The present application relates a device for measuring ground potential measurement of hand-wrapped insulation of a generator, and in particular to a device for measuring and transmitting DC voltage signals at generator terminals, which belongs to the field of electrical technology.

### BACKGROUND

It is widely known that turbo-generators cooled by water-hydrogen-hydrogen often experience accidents such as insulation breakdowns and short-circuit due to poor quality of hand-wrapped insulation at the ends of the stator windings. Moreover, it is difficult to detect defects through DC withstand voltage tests. Therefore, the test item which is required to measure ground potential by applying DC voltage to hand-wrapped insulation of generator stator windings during handover, overhaul, and when necessary has been added in “Guide for measurement methods and evaluation of hand-wrapped insulation of generator stator winding applied DC voltage” (DLT 1612-2016). The principle of the test is as follows.

With reference to FIG. 1, the insulation condition of a certain part is judged by the voltage to ground and the leakage current measured at an insulation surface during the test. When there is a defect in the insulation at this part, the volume resistance R1 of the insulation decreases (normally much greater than the surface resistance), resulting in a reduction of the voltage drop across R1. Consequently, the voltage to ground at this part increases, and the leakage current flowing through the micro-ammeter also increases.

Currently, existing testing methods and devices, as exemplified by a publicly disclosed patent for “METHOD FOR MEASURING POTENTIAL TO GROUND OF hand-wrapped insulation ON GENERATOR (CN105093073A)” and “DEVICE FOR MEASURING POTENTIAL TO GROUND OF hand-wrapped insulation ON GENERATOR (CN204241622U)”, generally suffer from the following deficiencies.

The top of the test rod features a probe-like structure with a small contact surface. Before potential measurement, it needs to wrap the measurement part with tin foil first, which must be removed after the measurement is completed, while ensuring that no fragments fall off. This process is very time-consuming, labor-intensive, and uneconomical. Additionally, the voltage signal display device is fixed to the insulated test rod, causing both the measurement personnel and data recording personnel to stay in a high-voltage area, posing significant safety hazards.

### SUMMARY

To overcome the aforementioned deficiencies of the related technology, a device for measuring and transmitting DC voltage signals at generator terminals is provided according to the present application. This device improves work efficiency, reduces safety risks to personnel and equipment, promotes environmental protection, and ultimately enhances economic benefits.

The following technical solutions are provided to solve the technical problems in the present application.

A device for measuring and transmitting DC voltage signals at generator terminals includes:
an insulated test rod internally provided with a standard resistor and a grounding interface,
a roller-type measuring head positioned at an outer end of the insulated test rod and connected to the standard resistor and the grounding interface via a conductor, and
a voltage signal display arranged outside the insulated test rod and wirelessly connected to the roller-type measuring head.

As a further improvement to the technical solution, the roller-type measuring head includes a metal roller and a conductive sponge wrapped around an outer circumference of the metal roller, both of the metal roller and the conductive sponge being connected to the standard resistor.

As a further improvement to the technical solution, the metal roller is wrapped with a layer of conductive sponge on the outside.

As a further improvement to the technical solution, the insulated test rod further includes a wireless signal transmitter inside, which is connected between the standard resistor and the grounding interface through a conductor. The voltage signal display includes a wireless signal receiver, and the voltage signal display and the insulated test rod transmit voltage signals wirelessly through the wireless signal transmitter and the wireless signal receiver.

As a further improvement to the technical solution, the roller-type measuring head is connected to the insulated test rod through a metal connecting rod, and the roller-type measuring head is also connected to the wireless signal transmitter through a wire.

As a further improvement to the technical solution, one end of the standard resistor is connected to the metal connecting rod, and the other end is connected to a positive input terminal of the wireless signal transmitter, and a negative input terminal of the wireless signal transmitter is connected to the grounding interface.

As a further improvement to the technical solution, the standard resistor is a 1MΩ standard resistor, the wireless signal transmitter adopts the AB433F2A module, and the wireless signal receiver adopts the AB433F2A-PDX module.

As a further improvement to the technical solution, the voltage signal display includes a display housing, with the wireless signal receiver and a power module disposed within the display housing. The display housing is provided with a digital display meter and a power switch, and both of the wireless signal receiver and the power module are connected to the digital display meter.

As a further improvement to the technical solution, the power module includes a 220V AC power interface and a 24V energy storage battery, both of which are located within the display housing.

As a further improvement to the technical solution, the insulated test rod includes a rod body, which is assembled in a detachable manner by sequentially connecting a head rod body, a plurality of intermediate rod bodies, and a tail rod body, with the standard resistor, the grounding interface, and the wireless signal transmitter all being disposed within the head rod body.

With the aid of the aforementioned technical solution, compared to the related technology, the device for measuring and transmitting DC voltage signals at generator terminals provided according to the present application eliminates the need to attach and remove tin foil on the measurement site through the incorporation of the roller-type measuring head. This not only significantly improves on-site work efficiency but also saves on the tin foil, enhancing economic benefits, promoting efficiency and low carbon emissions, and contributing to environmental protection. Furthermore, it provides a more reliable guarantee for the safety of the equipment under test as well as the safety of the testing personnel.

### BRIEF DESCRIPTION OF DRAWINGS

The present application is further described in detail below with reference to the accompanying drawings and embodiments.

FIG. 1 is a measurement schematic view of the conventional technology;

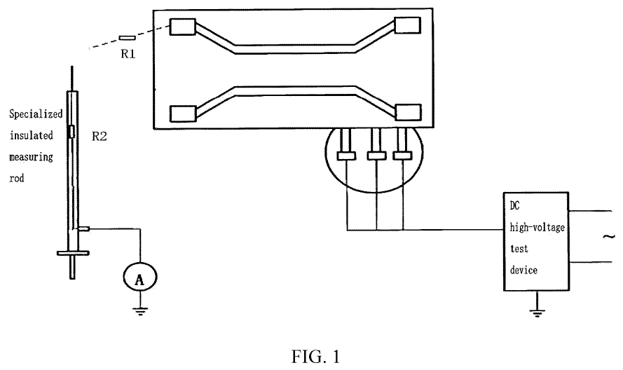

FIG. 2 is a schematic structural view of a device for measuring and transmitting DC voltage signals at generator terminals according to an embodiment of the present application.

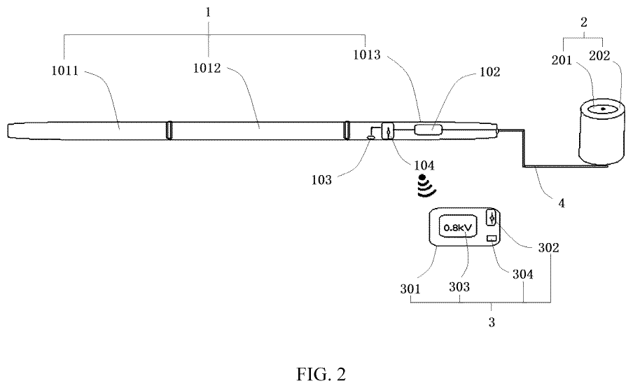

Reference numerals in FIG. 2 are listed as follows:
1 insulated test rod, 101 rod body, 1011 head rod body, 1012 intermediate rod body, 1013 tail rod body, 102 standard resistor, 103 grounding interface, 104 wireless signal transmitter;
2 roller-type measuring head, 201 metal roller, 202 conductive sponge,
3 voltage signal display, 301 display housing, 302 wireless signal receiver, 303 digital display meter, 304 power switch,
4 metal connecting rod.

### DETAILED DESCRIPTION OF THE EMBODIMENTS

In order to make the objective, the technical solutions and advantages of the embodiments of the present application more clear, the technical solutions in the embodiments of the present application are described clearly and completely below in conjunction with the drawings of the embodiments of the present application. Apparently, the embodiments described below are only some embodiments rather than all the embodiments of the present application. Based on the embodiments in the present application, all other embodiments obtained by those skilled in the art without creative efforts belong to the protection scope of the present application.

FIG. 2 shows a schematic structural view of a preferred embodiment of the present application. A device for measuring and transmitting DC voltage signals at generator terminals shown in the figure includes:
an insulated test rod 1 internally provided with a standard resistor 102 and a grounding interface 103;
a roller-type measuring head 2 positioned at an outer end of the insulated test rod 1, where the roller-type measuring head 2 is made of metallic material with good electrical conductivity and is connected to one end of the standard resistor 102 through a conductor; and
a voltage signal display 3, which is provided inside a case and is electrically connected to the voltage signal receiver.

In the embodiment of the present application, the insulated test rod 1 and the roller-type measuring head 2 are used in combination to measure the potential to ground by applying DC voltage to the hand-wrapped insulation of the generator stator windings. By using the roller-type measuring head 2 instead of the conventional probe-type measuring head, the process of attaching and removing aluminum foil at the measurement site is eliminated. Additionally, since the voltage signal display 3 is separately disposed from the insulated test rod 1 and is wirelessly connected to the insulated test rod 1, it addresses a series of deficiencies in the conventional technology caused by wrapping the aluminum foil at the measurement site and having the voltage signal display device fixed to the insulated test rod 1. This results in improved work efficiency, reduced safety risks to personnel and equipment, benefits to environmental protection, and enhanced economic benefits.

In a further optional embodiment of the present application, the roller-type measuring head 2 includes a metal roller 201 and a conductive sponge 202 wrapped around an outer circumference of the metal roller 201. Both of the metal roller 201 and the conductive sponge 202 are connected to the standard resistor 102.

During the operation of the roller-type measuring head 2, by moving the insulated test rod 1 up and down by hand, the metal roller 201 rolls on the measurement site accordingly, performing sampling measurements at different locations.

In a further optional embodiment of the present application, the metal roller 201 is wrapped with a layer of conductive sponge 202 on the outside. With the presence of the conductive sponge 202 on the surface of the metal roller 201, even if the surface of the measurement site is uneven, it can achieve contact without dead angles, thus avoiding measurement blind spots.

In a further optional embodiment of the present application, the insulated testing rod 1 is further internally provided with a wireless signal transmitter 104, which is connected between the standard resistor 102 and the grounding interface 103 through a conductor. The voltage signal display 3 is provided with a wireless signal receiver 302, and the voltage signal display 3 and the insulated testing rod 1 transmit voltage signals wirelessly through the wireless signal transmitter 104 and the wireless signal receiver 302.

The wireless signal receiver 302 is communicated with the wireless signal transmitter 104 through wireless signals. The wireless signal transmitter 104 sends signals to the wireless signal receiver 302 via wireless transmission. The wireless signal receiver 302 receives signals sent by the wireless signal transmitter 104 in a wireless manner and transmits the signals to a digital display meter 303. The digital display meter 303 converts the current signals received by the wireless signal receiver 302 into voltage signals and displays the values in digital form.

In a further optional embodiment of the present application, the roller-type measuring head 2 is connected to the insulated test rod 1 through a solid metal connecting rod 4, and the roller-type measuring head 2 is also connected to a wireless signal transmitter 104 via a wire.

The metal connecting rod 4 not only achieves the hardware connection between the metal roller 201 and the insulated test rod 1, but also ensures a good electrical connection between the metal roller 201 and the standard resistor 102, facilitating the transmission of electrical signals measured by the metal roller 201 and the conductive sponge 202.

In a further optional embodiment of the present application, one end of the standard resistor 102 is connected to the metal connecting rod 4, and the other end is connected to a positive input terminal of the wireless signal transmitter 104. A negative input terminal of the wireless signal transmitter 104 is connected to the grounding interface 103.

In a further specific embodiment of the present application, the standard resistor 102 may adopt a 1MΩ standard resistor. Since the outlet voltage of most generators on the market is 20 kV, the applied voltage at the measurement terminal is also 20 kV. If the loop impedance of the measurement device is 1MΩ, the maximum current in the loop is 20 mA (assuming the hand-wrapped insulation is completely damaged and the insulation is 0). The wireless signal transmitter 104 may adopt the AB433F2A module, which typically includes a suction cup antenna, capable of collecting measured DC current signals ranging from 0˜20 mA and transmitting them wirelessly to the wireless signal receiver 302. The wireless signal receiver 302 may adopt the AB433F2A-PDX module, which also includes a suction cup antenna, capable of receiving the DC current signals sent from the wireless signal transmitter 104.

In a further optional embodiment of the present application, the voltage signal display 3 includes a display housing 301, within which the wireless signal receiver 302 and a power module are arranged. The display housing 301 is provided with a digital display meter 303 and a power switch 304, and both of the wireless signal receiver 302 and the power module are connected to the digital display meter 303.

In specific implementation, the display housing 301 may be made of metal. The digital display meter converts the current signals from the wireless signal receiver 302 into voltage signals and displays them in Arabic numerals, with 0˜20 mA corresponding to 0˜20 kV, respectively. By operating the power switch 304, the digital display meter 303 can be powered on or off. This allows the digital display meter 303 to wirelessly display the real-time measurement of the voltage at a distance, enabling convenient reading of the voltage value.

In a further optional embodiment of the present application, the power module includes a 220V AC power interface and a 24V energy storage battery, both of which are located within the display housing 301. The 220V power interface and the energy storage battery provide AC and DC power to the digital display meter, respectively.

In specific implementation, the power module consists of both a 220V AC power module and a 24V energy storage battery module, specifically by integrating a power circuit with a 220V AC power interface and a 24V energy storage battery within the display housing 301. When using 220V AC power, the external 220V AC power source is connected through the 220V AC power interface, and then connected to the digital display meter 303 through its power circuit. Also, the 24V energy storage battery can be charged. When the 220V AC power source is unavailable, the 24V energy storage battery installed within the display housing 301 can be directly electrically connected to the digital display meter 303.

In a further optional embodiment of the present application, the insulated test rod 1 includes a rod body 101, which is assembled in a detachable manner by sequentially connecting a head rod body 1011, multiple intermediate rod bodies 1012, and a tail rod body 1013. The standard resistor 102, the grounding interface 103, and the wireless signal transmitter 104 are all housed within the head rod body 1011.

The configuration of the head rod body 1011, the intermediate rod bodies 1012, and the tail rod body 1013 facilitates the adjustment of the overall length of the insulated test rod 1. These components can be connected in a detachable manner through various mating interfaces such as snap-fits, threaded connections, or clasp connections to complete the sectional assembly. In terms of material, the rod body 101 may be made from common solid fiberglass epoxy resin tubing for durability and strength.

The device for measuring and transmitting DC voltage signals at generator terminals according to an embodiment of the present application exhibits the following technical advantages.

### 1) Improved Work Efficiency

In the conventional technology for DC voltage measurement, the measurement site requires the attachment of tin foil. This preparation work alone requires five people and approximately four hours to complete. Additionally, removal of the tin foil after testing is both time-consuming and labor-intensive.

The device according to the embodiment of the present application replaces the conventional probe-type measuring head with a roller-type measuring head 2, eliminating the need to attach the tin foil. The design concept of using the roller combined with the conductive sponge 202 significantly reduces preparation time and simplifies operation, thereby greatly improving work efficiency.

### 2) Reduced Equipment Safety Risks

The conventional technology requires the attachment of the tin foil, with a thickness between 0.01 mm and 0.02 mm, to the measurement site. The tin foil is highly prone to breaking during attachment and removal. If fragments fall into the gaps within the generator casing and are not promptly discovered and cleared, they pose a significant risk to the safe operation of the generator. The device according to the embodiment of the present application eliminates the need to attach the tin foil, thus avoiding the risk of fragment fallout.

### 3) Promoting Environmental Protection and Enhancing Economic Benefits

The tin foil used in the conventional technology is basically non-reusable and can only be discarded, resulting in significant waste of resources, which is neither economical nor environmentally friendly. The device according to the embodiment of the present application eliminates the need to attach the tin foil by covering the metal roller 201 with the conductive sponge 202. The conductive sponge 202 has a long service life, contributing to both considerable economic benefits and environmental protection.

### 4) Reduced Personnel Safety Risks

In the conventional technology, the voltage signal display device is fixed to the insulated test rod 1, with a small display interface and backlighting issues, making data recording extremely inconvenient. When recording personnel observe test data, they are positioned very close to the measurement personnel, increasing the risk of collisions and mutual interference during measurement and movement, posing risks of falls and electric shocks.

The device according to the embodiment of the present application adopts a wireless transmission method with a transmission distance of up to 1 km. This enables the recording personnel to read the data from the signal display device remotely, allowing them to stay away from high-voltage hazardous areas while effectively avoiding safety hazards caused by mutual interference between the measurement personnel and recording personnel, thereby enhancing safety.

The foregoing embodiments are only preferred embodiments of the present application and are not meant to limit the present application in any form. All simple modifications and equivalent variations made based on the technical essence of the present application fall within the protection scope of the technical solutions of the present application.

What is claimed is:

1. A device for measuring and transmitting DC voltage signals at generator terminals, comprising:
an insulated test rod internally provided with a standard resistor and a grounding interface,
a roller-type measuring head positioned at an outer end of the insulated test rod and connected to the standard resistor and the grounding interface via a conductor, and
a voltage signal display arranged outside the insulated test rod and wirelessly connected to the roller-type measuring head.

2. The device for measuring and transmitting DC voltage signals at generator terminals according to claim 1, wherein the roller-type measuring head comprises a metal roller and a conductive sponge wrapped around an outer circumference of the metal roller, both of the metal roller and the conductive sponge being connected to the standard resistor.

3. The device for measuring and transmitting DC voltage signals at generator terminals according to claim 2, wherein the metal roller is wrapped with a layer of conductive sponge on the outside.

4. The device for measuring and transmitting DC voltage signals at generator terminals according to claim 2, wherein the insulated test rod is internally provided with a wireless signal transmitter, which is connected between the standard resistor and the grounding interface through a conductor; and
the voltage signal display is internally provided with a wireless signal receiver, and the voltage signal display and the insulated test rod transmit voltage signals wirelessly through the wireless signal transmitter and the wireless signal receiver.

5. The device for measuring and transmitting DC voltage signals at generator terminals according to claim 4, wherein the roller-type measuring head is connected to the insulated test rod through a metal connecting rod, and the roller-type measuring head is also connected to the wireless signal transmitter through a wire.

6. The device for measuring and transmitting DC voltage signals at generator terminals according to claim 5, wherein one end of the standard resistor is connected to the metal connecting rod, and the other end is connected to a positive input terminal of the wireless signal transmitter, and a negative input terminal of the wireless signal transmitter is connected to the grounding interface.

7. The device for measuring and transmitting DC voltage signals at generator terminals according to claim 6, wherein the standard resistor is a 1MΩ standard resistor, the wireless signal transmitter adopts the AB433F2A module, and the wireless signal receiver adopts the AB433F2A-PDX module.

8. The device for measuring and transmitting DC voltage signals at generator terminals according to claim 4, wherein the voltage signal display comprises a display housing, with the wireless signal receiver and a power module disposed within the display housing, and the display housing is provided with a digital display meter and a power switch, both of the wireless signal receiver and the power module being connected to the digital display meter.

9. The device for measuring and transmitting DC voltage signals at generator terminals according to claim 8, wherein the power module comprises a 220V AC power interface and a 24V energy storage battery, both of which are located within the display housing.

10. The device for measuring and transmitting DC voltage signals at generator terminals according to claim 9, wherein the insulated test rod comprises a rod body, which is assembled in a detachable manner by sequentially connecting a head rod body, a plurality of intermediate rod bodies, and a tail rod body, with the standard resistor, the grounding interface, and the wireless signal transmitter all being disposed within the head rod body.
